(19) United States
(12) Patent Application Publication
(10) Pub. No.: US 2006/0105912 A1
(43) Pub. Date: May 18, 2006

(54) Microstructured catalyst body and method for production thereof

(76) Inventors: Johannes Konle, Voehringen (DE); Hartmut Presting, Blaustein (DE); Marc Sommer, Ulm (DE)

Correspondence Address: STEPHAN A. PENDORF, P.A., PENDORF & CUTLIFF, 5111 MEMORIAL HIGHWAY, TAMPA, FL, 33634, US

(21) Appl. No.: 10/525,359

(22) PCT Filed: Aug. 20, 2003
(86) PCT No.: PCT/EP03/09203

§ 371 Date: Nov. 3, 2005

(30) Foreign Application Priority Data
Aug. 23, 2002 (DE) 102395500
Sep. 12, 2002 (DE) 102430020

(51) Int. Cl. B01J 21/04; C23C 14/00

(52) U.S. Cl. 502/439; 204/192.34

(57) ABSTRACT

The invention relates to a catalyst body with one or several layer elements with etched cavities, through which flowing media may flow, such as for example, pores or channels. The cavities are essentially arranged perpendicular to the layer elements and the production is by means of etching methods from semiconductor technology.

### CROSS REFERENCE TO RELATED APPLICATION

This application is a national stage of PCT/EP2003/009203 filed Aug. 20, 2003 and based upon DE 102 39 550.0 filed Aug. 23, 2002 and DE 102 43 002.0 filed Sep. 17, 2002 under the International Convention.

### BACKGROUND OF THE INVENTION

1. Field of the Invention

The invention deals with a microstructured catalyst body for chemical reforming units for application in for example fuel cell systems and a method of fabrication thereof.

2. Related Art of the Invention

As a result of more and more drastic repercussions of obtaining energy from fossil fuels, and with respect to a natural resource saving use of energy, fuel cells have a very high market potential with respect to efficient and environment-friendly alternative energy sources. Also in the automobile industry sector fuel cell technology has successfully been tested for a long time. Thereby one variant consists in conversion of hydrogen from liquid fuels such as methanol or conventional gasoline on board of the automobile. For that purpose a so-called reforming process is necessary which converts long chain hydrocarbons into hydrogen and carbon dioxide. In this case a method is applied where the input components (water and/or air and liquid hydrocarbons) release the end products such as for example hydrogen under the action of a catalyst.

This process can be divided into two steps. In the reforming reaction which, depending on the used method can be strongly endothermic, exothermic or autothermic, hydrocarbon together with water and air are converted to—among others—carbon monoxide and molecular hydrogen. Since the liquid primary products can be exposed to a high pressure and since the part of hydrogen (which could not be converted in the fuel cell) still residing in the exhaust gas can be used in a separate burner to heat the first reactor level this process bears a high potential of miniaturizing all involved components. Thereto, however, a high efficiency of the first step is needed where the required hydrogen is created catalytically.

For the described reforming process usually so-called catalytic reformers are applied. Usually this concerns either porous metal structures or foams or micro-structured layer devices with a large surface usually coated with a catalytic active layer. Decisive criteria for the reaction rate of the reactants is on the one hand the surface/volume ratio of the reactor, the pressure difference along the microstructure and on the other hand the heat transfer at the interface to the reactant gases. Furthermore also the temperature stability and the steadiness of the used material to temperature cycles play an important role.

In the U.S. Pat. No. 5,811,062 such a catalytic reformer is introduced. The catalyst body used in the described reformer basically consists of a stack of internally connected element layers from metal, ceramics or from semiconductor material in which, by a micro-structuring method, for example an etch process, cavities such as channels or pores are formed. The geometry of microstructures is hereby chosen such that the flow of the reactants from single element to element occurs through macroscopic openings and on the other hand the flow of the reactants through the elements occurs parallel to the surface of in the elements inserted openings. This arrangement, however, has several drawbacks. The reactants change their flow direction several times when streaming through the reactor, which increases the flow resistance through the reformer. Further on the potential of miniaturization is very limited in this patent because there is only one cavity per layer element along the surface running which can be realised and due to stability reasons the thickness of the single layer elements cannot be less than a minimum value. In addition to that the method of fabrication of the reformer is complicated and thus expensive because the surface has to be supplied with numerous cavities and the single elements have different geometries in their openings.

### SUMMARY OF THE INVENTION

The task of the here proposed invention is to describe a catalyst body which can be simply and cost effectively manufactured and which has with minimal outer dimensions a maximum active inner surface as well as a very low flow resistance and describe a method if its fabrication.

### DETAILED DESCRIPTION OF THE INVENTION

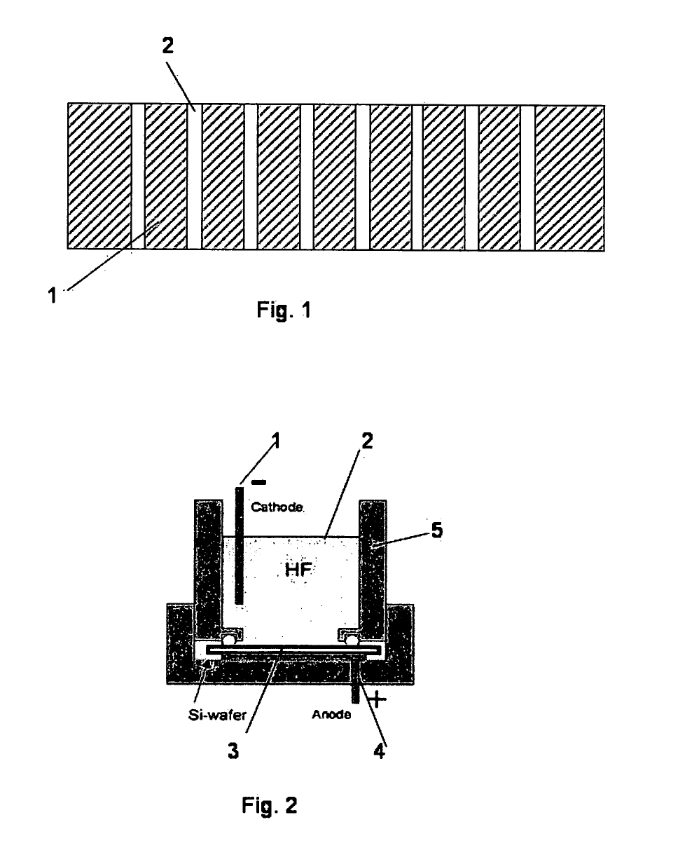

The proposed catalyst body consists of a stacked structure of single layer elements as sketched in FIG. 1 (cross section of a layer element). Here the cavities (2), for example pores or channels basically run perpendicular to the surface through all elements. This arrangement has a number of advantages. The reactants flow basically straight through the reactor. Thereby the flow resistance of the whole arrangement is reduced and the maximum conversion possible is considerably increased. Further on the proposed catalyst body can be excellently miniaturized because due to the perpendicular arrangement of the pores the minimum distance of the single pores can be drastically reduced. Nearest neighbour distances down to the range of 50 nm seem to be achievable without any problem; this value seems for the above described conventional structure completely unrealistic since single layer elements of this small thickness are neither manufacturable nor structurable. A further advantage of this invention consists in the fact that in contrast to the in the US patent described reforming device identical elements can be used which simplifies the fabrication of the proposed catalyst body considerably and thus makes it more cost effective because for structuring the elements the same process can be applied.

It is especially advantageous to use silicon or a silicon based compound alloy for the elements. The use of silicon for the support structure of the catalyst offers the possibility to optimize the geometry, porosity and the pore diameter in a very wide range. The pore diameter in silicon can be varied from roughly 0.8μ up to several 100μ and can so be adapted to the requirements of an optimal throughput, reaction kinetics and gas conversion. Silicon is further very temperature stable and due to the very mature process technology furthermore very cost effective.

A further on advantageous embodiment of this invention consists in the fact that the dimensions of the cavities parallel to the flow direction as well as perpendicular to it can be shaped variable. It is for example possible that the through the catalyst body running pores can be narrowed along the flow direction. Thereby it is possible to adjust an especially from the reaction kinetics point of view advantageous pressure and velocity profile in the reactor.

For improvement of the adhesion of the catalyst material to the support structure it is further on purposeful to deposit a metal layer on the support structure. Especially aluminium proved to be well suited for this purpose, since there are ample experiences about its processing in the semiconductor technology. By all means it is advantageous for an efficient catalytic action of the reformer to coat the inner surface with a catalytic active material. Especially well suited for that is Platinum, but there are also other catalyst materials possible.

To reduce the flow resistance of the catalyst body it is advantageous to reduce the number of so-called dead ends in the structure. For that it is necessary to precisely align the ends of each pore or channel at the interface between two adjacent elements. To achieve this it is especially purposeful to foresee alignment marks for the structuring process. The single stack elements can be furnished with oblique mesa flanks at the outer edges of the porous etched region which can be precisely aligned to the corresponding opening on the back surface of the pre-ceding element. These mechanical alignment marks can be fabricated by an additional step in the process of etching the pores into the substrate. Thus single stack elements can be precisely aligned and stacked on top of each other in an arbitrary number. The so achieved precision becomes vividly clear when one shows quite plainly that a so fabricated catalyst support structure with a total thickness of several cm which appears transparent when one looks through the pores.

For adjustment of the optimal reaction temperature it is advantageous to envisage an integrated resistance heater. For that the required heat conductivity of the conductivity profile can be adjusted by a proper doping of the silicon substrate. If one applies a voltage to the semiconductor catalyst body it will be heated by the flow of electric current. Via a current regulator the required reaction temperature can be achieved. Therefore it is especially advantageous to use semiconductors with a good thermal conductivity such as silicon for example.

It has been proved of value to fabricate the catalyst body according to the following procedure: a well-suited primary material consists for example of a 300μ thick, p-doped silicon substrate with 10 cm in diameter. First of all the pores are etched into the substrate for example by anodic etching or by a dry etch process which forms pores basically perpendicular to the substrate. Subsequently the porous etched silicon wafer can be sawed into pieces with the required dimensions which depending on the thickness of the used wafer can be stacked several times on top of each other and can be fixed in a housing of high temperature steel (such as Incornell or DIN 1.4841 for example) with a screwable cap to hold the elements in place. This is well suited since the following catalyst material deposition process is usually a high temperature process.

It is especially advantageous to use as wet chemical etch process of the silicon wafer the so-called “deep anodic etching” or “photo-anodic etching”. An exemplary arrangement is illustrated in FIG. 2. As electrolyte (2) an aqueous solution is used consisting of hydrofluoric (HF) acid, dimethylformamid and iso-propanol which is put in the holder (5). The etch process usually takes place galvanostatic, i.e. with constant current between the anode (4) and the cathode (1). Here the at the electrolyte/semiconductor wafer interface occurring depletion region (i.e. space charge region) plays a decisive role in the formation of the pores. The diffusion current of the carriers dominate depending on the form of the etched cavities to the currents caused by tunnelling or thermal excitation. An isotropic etch of the pores in the silicon wafer takes place when the nearest distance of the pores is less than twice the thickness of the depletion region because then the carrier transfer to the walls (catwalks) in between the pores is blocked. Because the space charge region is determined by the applied voltage and doping of the substrate the form, geometry and density of these cavities can be controlled by an intentional choice of these parameters. The diameter as well as the density of the etched pores can be adjusted by choice of the substrate doping for the so-called self assembled etching process. An essential advantage of this procedure is the achieved high surface/volume ratio. Since out of technological reasons it is impossible to etch a semiconductor wafer completely through by anodic etching the porous etched layer can be lifted by a special process. For that the current density is dramatically increased for several seconds when the desired etch depth is achieved. This leads to a drastic enhancement of carriers at the pore tips which finally leads to isotropic etching of silicon. Consequently due to the thin separation walls the layer with the etched pores is lifted from the substrate.

A further highly beneficial variant of the etch process is the use of dry chemical plasma etching. This method where the process gases C₄H₈ and SF₆ are applied allows a highly anisotropic etching with aspect ratios (diameter/pore depth ratio) of roughly 1:20 and more. For a wafer thickness of 300μ and more the diameter of the plasma etched pores can be 15μ and above. By this etch method the semiconductor substrate can be completely etched through, possible etch rates can be 80μ per hour.

The above described procedure of anodic etching of silicon can be modified in that way that by a pre-ceding photo-lithographic process the position of the pores at the wafer surface can be controlled externally and are not governed by the substrate's resistivity (i.e. doping). In connection with an alignment of the stack elements to each other dead ends in the catalyst body can be largely avoided. For that a 2μ thick silicon dioxide layer which is deposited at the wafer surface is structured by a photo-mask such that at the designated spots the pores can be etched first by an oxide etch such as buffered HF. By a subsequent etch of so-called inverted pyramids into the silicon substrate using potassium hydroxide (KOH)—the etch rate of which is very sensitive to certain crystal faces in silicon—the <111> face is practically not attacked whereas on the <100> face holes with an inverted pyramid form occur (angle between the <111> and the <100> face is 54°). For the subsequent anodic etching the base length of the inverted pyramids can be adjusted between 2μ and ˜20μ. Since the tips of these pyramids represent an inhomogeneity for the current these tips represent a preferred inhomogeneity, consequently the etch process starts right there and will due to its anisotropic character be continued into the substrate.

By this pre-defined etching it is for a stacking of several elements of these layers possible, for example by use of alignment marks, to fill a cavity with the length of the total reactor. In contrast to the disordered pores or the use of other micro porous materials in nature (such as metal foams, granulates i.e.) the pressure loss along the reactor is drastically minimised because there are no dead ends in this structure. It is especially interesting to combine the self-organized etching (without photolithographic pre-structuring) with the lithographic pre-structuring. It is for example possible to pre-etch a wafer by means of lithographic pre-structure and subsequent inverted pyramid etching, then turn the wafer upside down and etch it by self-assembled anodic etching from the backside all the way to the depth of the etch pits on the front side. Thus the advantages of self-organized etching (large surface) can be combined in a purposeful way with the advantages of the pre-defined etching (at least a one-side alignment of the elements to avoid dead ends in the structure).

Further on the proposed etch processes allow structuring wafers with almost arbitrary diameters, an essential prerequisite for a production friendly and cost effective fabrication method.

To improve the adhesion of the catalyst material to the support structure it is advantageous to coat the etched pores with a metal. Best suited here is aluminium which is also often applied in the mature silicon technology, Two ways of surface coating process with a metal are possible. Aluminium can either be deposited by evaporating from its melt under vacuum conditions onto the surface of the etched pores or a so-called sputtering process can deposit it. The latter is a plasma process where ionised particles from the plasma hit a metallic target (here aluminium) and punch out atoms from the target which are subsequently deposited on the sample lying underneath the target. Both methods are principally suited for coating the catalyst carrier. For the function of the reformer the thickness of the aluminium layer is not decisive. Therefore a deposition of a few nanometres of aluminium is enough, evidently for a metallic adhesion layer also materials such as copper, nickel or their alloys are suited. For a good catalytic performance of the reactor a platinum coating is for example very well suited.

Principally for a good adhesion of the catalytically active coating material to the metallic adhesion promotion layer an accommodation of the thermodynamic properties of the used materials is required; in particular materials with similar linear expansion coefficients should be used to minimise the strain of the different layers and thus the possibility that these layers separate during the temperature cycles. Thermal or plasma spraying can suitably provide the deposition of the catalytic active material.

The principle of the thermal spraying consists in the fact that the sprayed material which can be in powder or in bar form will be melted from a thermal source and will then be deposited onto the substrate from a melted liquid state. In the plasma spraying method the for the melting required energy is created by the plasma. In a centrally arranged, water cooled copper anode a gas stabilized arc with a very high energy density is ignited. The added plasma gas is ionised to plasma and leaves the ignition nozzle with high velocities (300-700 m/sec.) and at temperatures of 15,000 to 20,000K. The coating material in powder form is inserted by a carrier gas via feed channels into the plasma beam; it is melted there and accelerated with a high velocity onto the substrate.

The described fabrication methods allow the construction of the reactor with the proposed catalyst support body in a suitable way by choice of appropriate segments of the reactor. This way the different requirements of a catalytic reactor can be accounted for by a combination of segments of different number and stack construction according to the different envisaged application schemes.

In addition the excellent possibilities of micro structuring of the proposed catalytic body permit its use in applications with special requirements to the maximum construction volume possible. The use in fuel cell systems for mobile applications, especially in automobiles is of special importance.

1. A catalyst body with one or more layer elements with cavities which are etched and through which streamable media can flow, such as pores or channels wherein the cavities are basically perpendicular to the surface.

2. The catalyst body according to claim 1, wherein the layer elements consist basically of silicon or silicon compound alloy.

3. The catalyst body according to claim 1, wherein the dimensions of the cavities perpendicular to the flow direction of the medium vary.

4. The catalyst body according to claim 1, wherein the surface of the cavities has a metallic coating.

5. The catalyst body according to claim 1, wherein the inner surface of the cavities posses a catalytic active coating.

6. The catalyst body according to claim 1, wherein at least two of the layer elements have alignment marks.

7. The catalyst body according to claim 1, wherein the layer elements basically consist of electrically conducting material.

8. A method of fabrication of a catalyst body constructed from single layer elements with the following procedure steps:
etching of complete pores running through the substrate which basically run perpendicular to the layer surface
stacking of equally processed and etched elements on top of each other.

9. The method of fabrication according to claim 8 wherein the etching is performed by deep anodic or photo anodic etching.

10. The method of fabrication according to claim 8 where the etching is performed by a plasma etching process.

11. The method of fabrication according to claim 8, wherein additional alignment marks are foreseen on each of the layer elements.

12. The method of fabrication according to claim 8, wherein at least one surface is pre-structured by a photolithographic process.

13. The method of fabrication according to claim 8, wherein the surfaces of the etched cavities are coated by a metallic layer.

14. The method of fabrication according to claim 8, wherein the surfaces of the etched cavities are supplied with a catalytic active layer.

15. A catalytic reactor with a housing including feed and output gas lines for the reactants and a catalyst body inside, wherein the catalytic reactor has a catalyst body with one or more layer elements with cavities which are etched and through which streamable media can flow, such as pores or channels wherein the cavities are basically perpendicular to the surface.

16. The catalytic reactor according to claim 15 wherein the catalytic reactor is divided into several segments each segment consisting of the said described catalyst body.

17. A fuel cell system with a catalytic reactor as a reformer and a fuel cell, wherein a fuel cell has a catalytic reactor with a housing including feed and output gas lines for the reactants and a catalyst body inside thereby defined that it has a catalyst body with one or more layer elements with cavities which are etched and through which streamable media can flow, such as pores or channels wherein the cavities are basically perpendicular to the surface.
